(19) United States
(12) Patent Application Publication
(10) Pub. No.: US 2015/0201515 A1
(43) Pub. Date: Jul. 16, 2015

(54) SURFACE FINISH FOR CONDUCTIVE FEATURES ON SUBSTRATES

(71) Applicant: RF Micro Devices, Inc., Greensboro, NC (US)

(72) Inventors: Donald Joseph Leahy, Kernersville, NC (US); Jungwoo Lee, Greensboro, NC (US); John August Orlowski, Summerfield, NC (US); Howard Joseph Holyoak, High Point, NC (US)

(21) Appl. No.: 14/595,615

(22) Filed: Jan. 13, 2015

Related U.S. Application Data
(60) Provisional application No. 61/926,498, filed on Jan. 13, 2014.

(51) Int. Cl. H05K 7/06; H05K 13/00; H05K 1/09

(52) U.S. Cl. CPC H05K 7/06; H05K 1/09; H05K 13/0023; H05K 2201/10287; H05K 2201/10166

(57) ABSTRACT

An electronics module includes a non-conductive body, a first set of conductive features exposed on a surface of the non-conductive body, and a second set of conductive features exposed on the surface of the non-conductive body. The first set of conductive features is configured to connect to a wire bond component. The second set of conductive features is configured to connect to a flip chip component. A protective finish is provided over each one of the first set of conductive features and the second set of conductive features. The protective finish includes a layer of nickel less than 1 μm thick, a layer of palladium over the layer of nickel, and a layer of gold over the layer of palladium.

### RELATED APPLICATIONS

This application claims the benefit of provisional patent application Ser. No. 61/926,498, filed Jan. 13, 2014, the disclosure of which is hereby incorporated herein by reference in its entirety.

### FIELD OF THE DISCLOSURE

The present disclosure relates to electronics modules with protective finishes suitable for use with both flip chip and wire bond components.

### BACKGROUND

Electronics modules and printed circuit boards (PCBs) are often used to support and connect several electrical components. Generally, an electronics module and/or PCB includes a non-conductive body for support, and a plurality of conductive features for connecting the various electrical components. The conductive features may be any type of conductive structure and may include contact pads, conductive traces, vias, and/or the like. Electrical components such as resistors, capacitors, inductors, bond wires, and integrated circuits (ICs) are mounted to one or more exposed portions of the conductive features by a soldering process. For example, the conductive features may include one or more contact pads connected to one another by one or more conductive traces. An electrical component (such as a resistor, a capacitor, an inductor, an IC, etc.) may be mounted on the one or more conductive pads by the soldering process. Accordingly, one or more circuits may be formed on the electronics module and/or PCB.

The conductive features discussed above are often created by a copper etching process, wherein a thin copper sheet is laminated onto the non-conductive body and etched to form a connection pattern. The conductive properties and performance characteristics of the conductive features may degrade over time due to oxidation and exposure to the elements. Accordingly, a protective finish is generally deposited onto the one or more conductive features in order to preserve the conductive properties thereof.

While there are many protective finishes commercially available today, most if not all of these protective finishes are suitable for only a single type of electronics packaging system. For example, conventional protective finishes are generally suitable for either wire bond components or flip chip components, but not both. This is due to the different bonding types utilized for wire bond and flip chip components. Specifically, while the electrical connection points for a wire bond component do not need to support any structure, those for a flip chip component do. Accordingly, surface finishes for flip chip components require mechanical stability and reliability against forces such as shear. For purposes of illustration, an exemplary wire bond component 10 and electronics module 12 are shown in FIG. 1. As discussed above, the electronics module 12 includes a non-conductive body 14 and a number of conductive features 16. The wire bond component 10 is mounted to the non-conductive body 14, for example, via an adhesive of some kind. Each one of a number of contact pads on the wire bond component 10 are then connected to a corresponding one of the conductive features 16 on the electronics module 12 via a small wire 18, which is connected via a bonding process. As discussed above, a suitable protective finish 20 is generally provided over the conductive features 16 of the electronics module 12.

FIG. 2 shows an exemplary flip chip component 22 and the electronics module 12. While the electronics module 12 is substantially similar to that shown in FIG. 1, the flip chip component 22 connects to the electronics module 12 in a completely different way. Specifically, one or more extruding connection points 24 (usually formed by either copper pillars or solder balls) are aligned with a corresponding conductive feature 16 on the electronics module 12, and a solder reflow process is performed to securely bond the two. Notably, the particular layout of the conductive features 16 on the electronics module 12 is completely different for the flip chip component 22 than for the wire bond component 10. As a further difference, a different surface finish 20 (as indicated by the different shading in 20 between FIGS. 1 and 2) is required for the flip chip component 22 than for the wire bond component 10, as the particular requirements of each component for the structural properties, the electrical properties, or both of the surface finish used, differ between the components. As shown in FIG. 2, the flip chip component 22 is both electrically and mechanically connected to the electronics module 12 via the solder connections formed between the extruding connection points 24 and the corresponding conductive features 16. Accordingly, the bonds between these extruding connection points 24 and the conductive features 16 must withstand significant mechanical forces such as sheer. Conventional protective finishes used along with wire bond components do not provide suitable mechanical stability or reliability, and therefore a different protective finish must be used with flip chip components than with wire bond components.

In some situations, it may be necessary to utilize both wire bond and flip chip components on a single electronics module. As discussed above, the protective finishes used for wire bond and flip chip components are typically not compatible with one another. Accordingly, FIGS. 3 and 4A through 4C show a conventional process for separately providing multiple protective finishes on an electronics module including both wire bond and flip chip components. First, an electronics module 26 is provided that includes a non-conductive body 28, a first set of conductive features 30A configured to connect a wire bond component to the electronics module 26, and a second set of conductive features 30B configured to connect a flip chip component to the electronics module 26 (step 100 and FIG. 4A). A first mask 32 is then provided over the second set of conductive features 30B and any exposed portions of the non-conductive body 28 such that only the first set of conductive features 30A are exposed (step 102 and FIG. 4B), and a first protective finish 34 is provided over the first set of conductive features 30A (step 104 and FIG. 4C). Notably, since the first set of conductive features 30A are configured to connect a wire bond component to the electronics module 26, the first protective finish 34 is one that is compatible with a wire bond component.

The first mask 32 is then removed (step 106 and FIG. 4D). A second mask 36 is then provided over the first set of conductive features 30A such that only the second set of conductive features 30B are exposed (step 108 and FIG. 4E), and a second protective finish 38 is provided over the second set of conductive features 30B (step 110 and FIG. 4F). Since the second set of conductive features 30B are configured to connect a flip chip component to the electronics module 26, the second protective finish 38 is one that is compatible with a flip chip component. The second mask 36 is then removed (step 112 and FIG. 4G). A wire bond component 40 may then be coupled to the electronics module 26 and the first set of conductive features 30A, for example, via a bonding process (step 114 and FIG. 4H). Finally, a flip chip component 42 may be coupled to the electronics module 26 via the second set of conductive features 30B, for example, via a bonding process (step 116 and FIG. 4I). While the foregoing process produces an electronics module 26 that is suitable for both wire bond and flip chip components, it requires depositing two separate protective finishes, which significantly complicates the manufacturing of the electronics module 26 and increases the cost thereof.

Accordingly, there is a need for an electronics module that is easy to manufacture, robust, and capable of supporting both wire bond and flip chip components.

### SUMMARY

The present disclosure relates to electronics modules with protective finishes suitable for use with both flip chip and wire bond components. In one embodiment, an electronics module includes a non-conductive body, a first set of conductive features exposed on a surface of the non-conductive body, and a second set of conductive features exposed on the surface of the non-conductive body. The first set of conductive features is configured to connect to a wire bond component. The second set of conductive features is configured to connect to a flip chip component. A protective finish is provided over each one of the first set of conductive features and the second set of conductive features. The protective finish includes a layer of nickel less than 1 μm thick, a layer of palladium over the layer of nickel, and a layer of gold over the layer of palladium. By using the protective finish including a layer of nickel less than 1 μm thick, a layer of palladium over the layer of nickel, and a layer of gold over the layer of palladium, both flip chip and wire bond components may be connected to the electronics module while utilizing the single protective finish, thereby saving both time and cost in the production of the electronics module.

In one embodiment, a method for manufacturing an electronics module includes the steps of providing a non-conductive body including a first set of conductive features suitable for connecting a wire bond component to the electronics module and a second set of conductive features suitable for connecting a flip chip component to the non-conductive body and providing the same protective finish over the first set of conductive features and the second set of conductive features. The protective finish includes a layer of nickel less than 1 μm thick, a layer of palladium over the layer of nickel, and a layer of gold over the layer of palladium. By using the protective finish including a layer of nickel less than 1 μm thick, a layer of palladium over the layer of nickel, and a layer of gold over the layer of palladium, a wire bond component may be coupled to the first set of conductive features and a flip chip component may be coupled to the second set of conductive features while utilizing only one protective finish. Accordingly, both time and cost in the production of the electronics module can be saved.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a conventional wire bond component.

FIG. 2 illustrates a conventional flip chip component.

FIG. 3 is a block diagram showing a conventional method for manufacturing an electronics module.

FIGS. 4A through 4I illustrate the conventional method for manufacturing an electronics module described in FIG. 3.

FIG. 5A illustrates an electronics module according to one embodiment of the present disclosure.

FIG. 5B illustrates the electronics module shown in FIG. 5A including components attached to the electronics module according to one embodiment of the present disclosure.

FIG. 5C illustrates an expanded view of a conductive feature of the electronics module shown in FIGS. 5A and 5C according to one embodiment of the present disclosure.

FIG. 6 is a block diagram showing a method for manufacturing an electronics module according to one embodiment of the present disclosure.

FIGS. 7A through 7G illustrate the method for manufacturing an electronics module described in FIG. 6.

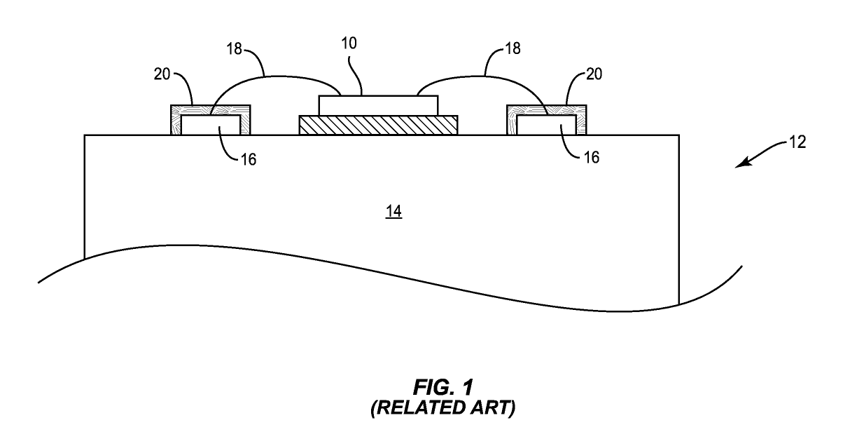

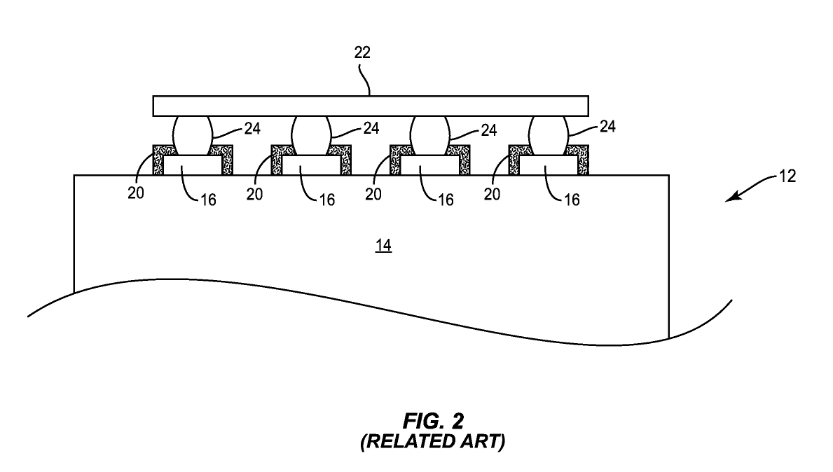

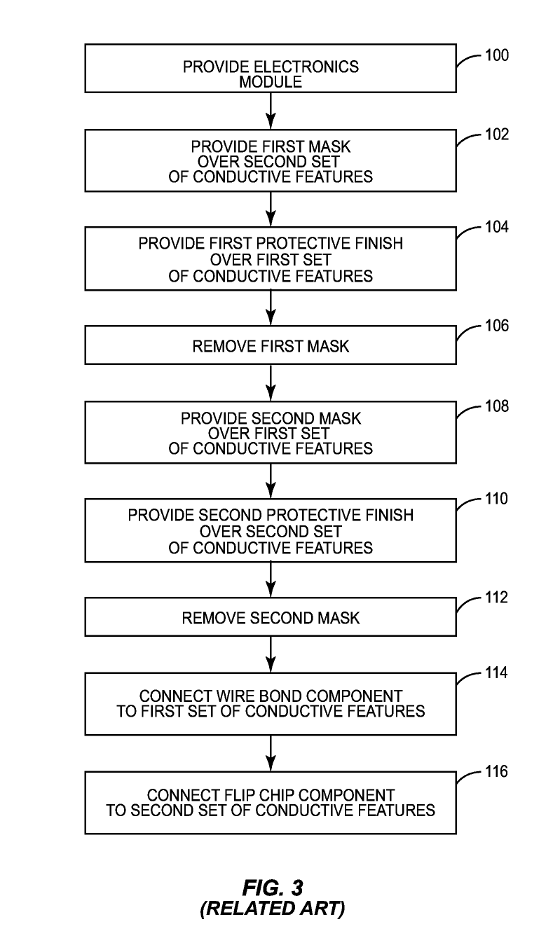

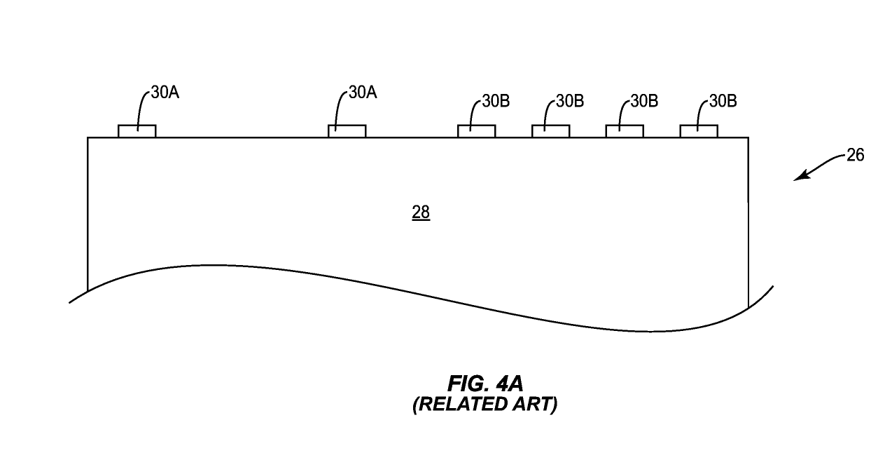

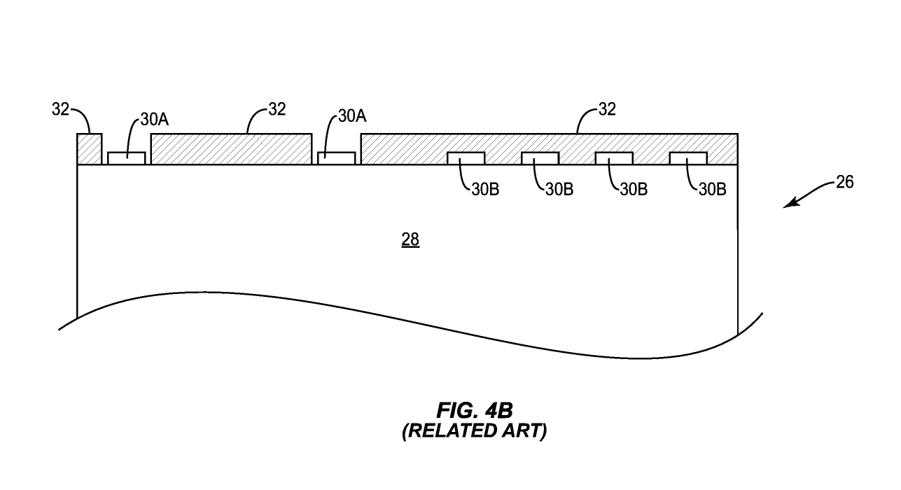

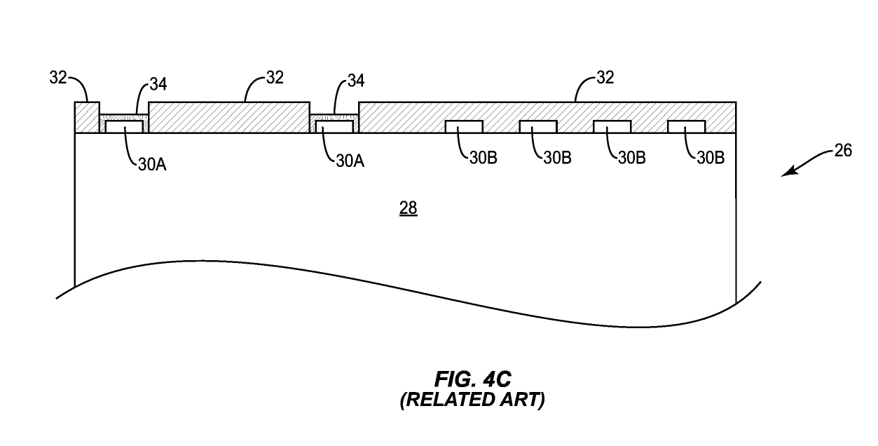

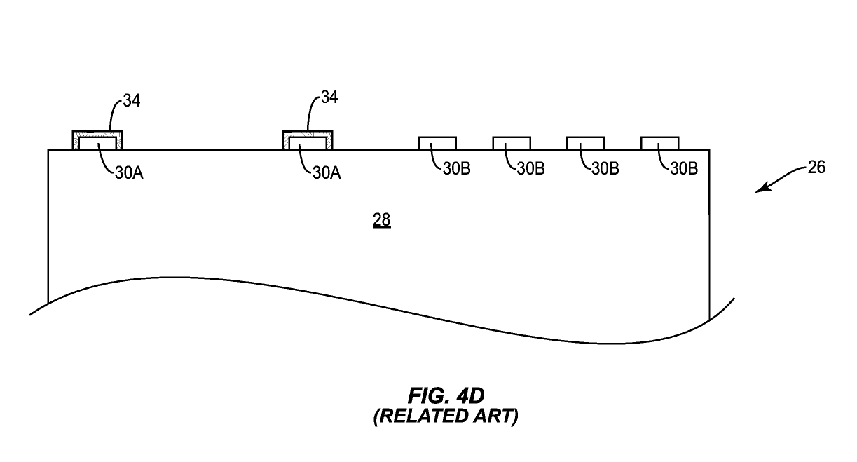

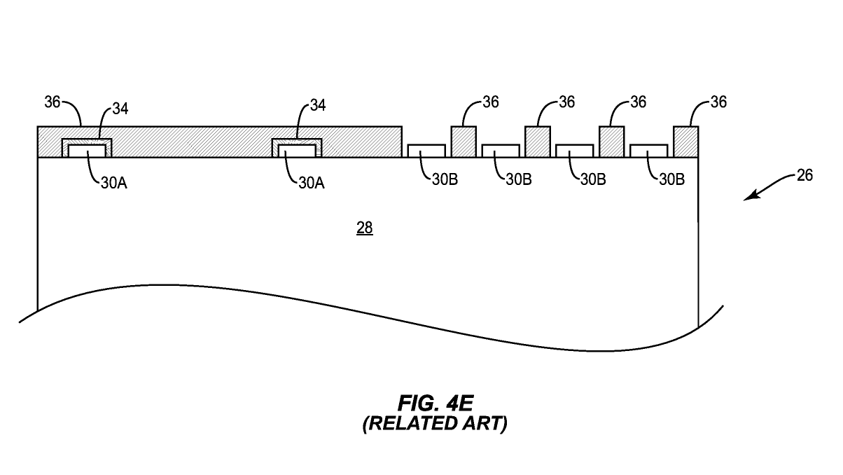

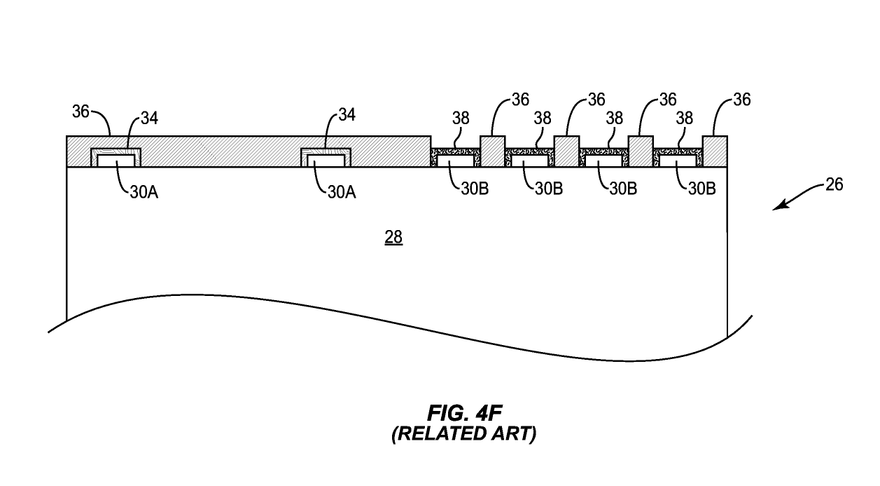

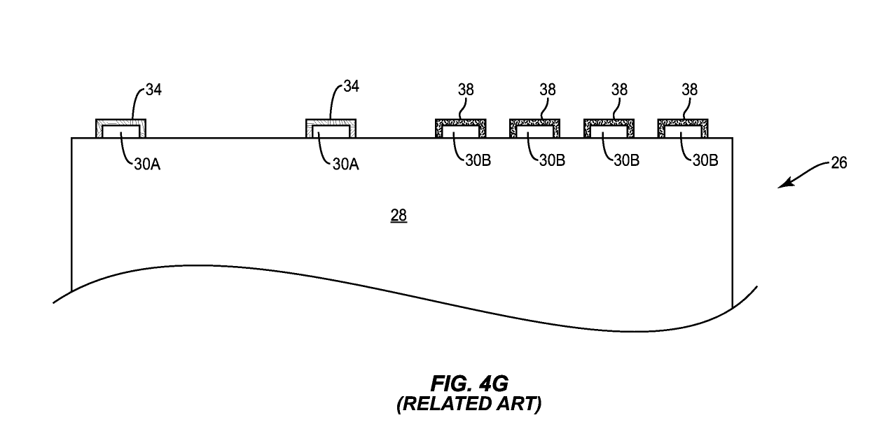

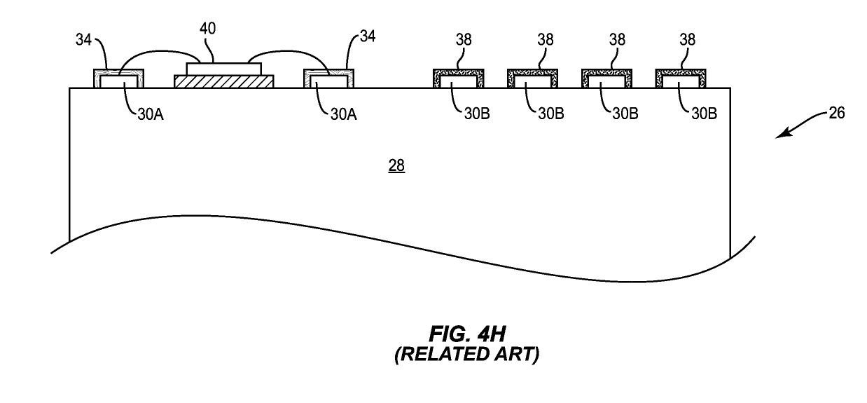

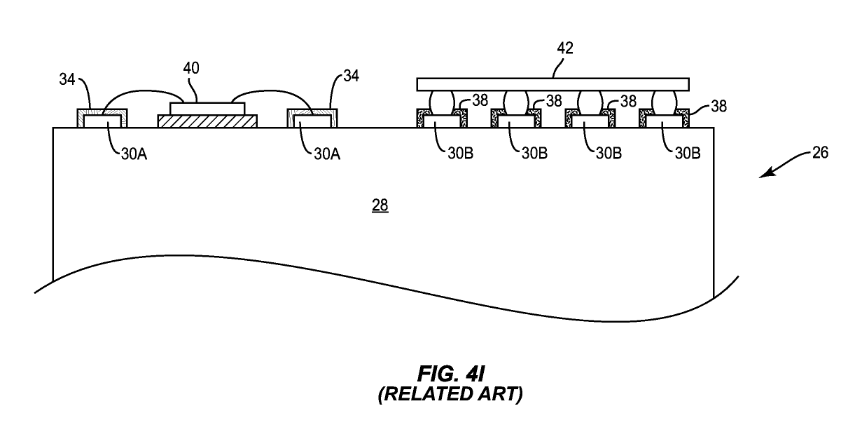

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

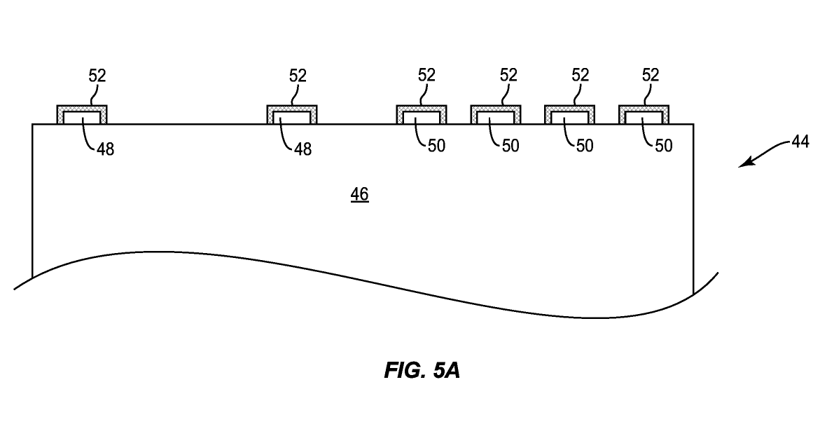

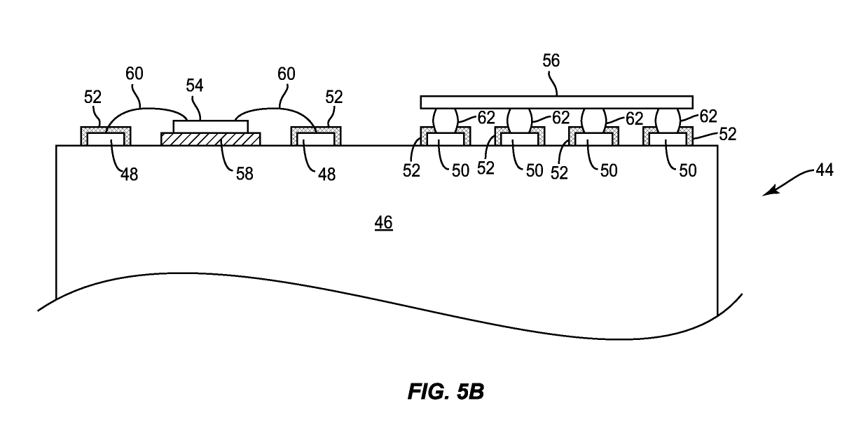

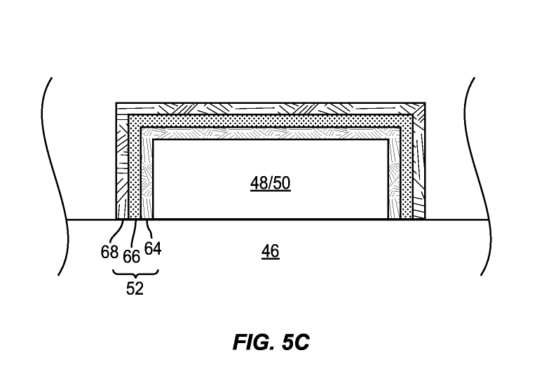

FIG. 5A shows an electronics module 44 according to one embodiment of the present disclosure. The electronics module 44 includes a non-conductive body 46, a first set of conductive features 48, and a second set of conductive features 50. The first set of conductive features 48 and the second set of conductive features 50 are on a surface of the non-conductive body. The first set of conductive features 48 are arranged in order to connect to a wire bond component, while the second set of conductive features 50 are arranged to connect to a flip chip component. Accordingly, the electronics module 44 is configured to connect to both wire bond and flip chip components. As discussed above, the conductive features may be contact pads for connecting components to the electronics module 44. Additional conductive features such as additional contact pads, conductive traces, vias, and/or the like are likely also included in the electronics module 44, but are not shown for brevity. The specifics of these conductive features will be fully appreciated by those of ordinary skill in the art.

A protective finish 52 is located over each one of the first set of conductive features 48 and the second set of conductive features 50. Notably, the protective finish 52 provided over the first set of conductive features 48 and the second set of conductive features 50 is the same protective finish. Accordingly, the manufacturing process of the electronics module 44 may be significantly streamlined, as discussed in detail below. In one embodiment, the protective finish 50 includes a layer of nickel, a layer of palladium over the layer of nickel, and a layer of gold over the layer of palladium. Known in the industry as an ENEPIG protective finish, conventional ENEPIG formulations often include a relatively thick (i.e., >3 μm) layer of nickel. The inventors discovered that conventional ENEPIG protective finishes are generally unsuitable for flip chip components due to the thick layer of nickel that is conventionally included therein. Specifically, using a thick layer of nickel results in unreliable and structurally unsound solder joints when connecting a flip chip component to a conductive feature with an ENEPIG protective finish. Accordingly, the protective layer 52 shown in FIG. 5A includes a layer of nickel less than 1 μm thick, a layer of palladium over the layer of nickel, and a layer of gold over the layer of palladium. The layer of palladium may be between about 0.03 μm and 0.2 μm thick. The layer of gold may be between about 0.03 μm and 0.15 μm thick. The inventors discovered that using a thin nickel layer in an ENEPIG process allows for a surface finish that is compatible with both wire bond and flip chip components, and can therefore be used to significantly streamline the manufacturing of the electronics module 44 as discussed in detail below.

The non-conductive body 46 may be any suitable material. In one embodiment, the non-conductive body 46 is a laminate material such as that typically used to support printed circuit boards (PCBs). Specifically, the non-conductive body 46 may be formed of any material that acts as an electrical insulator such as a multifunctional epoxy, an epoxy blend, a bismaleimide-triazine (BT) resin, a ceramic, or the like.

FIG. 5B shows the electronics module 44 including a wire bond component 54 connected to the first set of conductive features 48 and a flip chip component 56 coupled to the second set of conductive features 50. The particular details of the wire bond component 54 and the flip chip component 56 are shown for exemplary purposes only. The flip chip component 56 is coupled to the non-conductive body 46 via an adhesive 58, and is electrically connected to the first set of conductive features 48 via a number of wire bonds 60. The flip chip component 56 is electrically coupled to the second set of conductive features 50 via a number of solder balls 62. In other embodiments, the flip chip component 56 may be attached to the second set of conductive features 50 via a number of copper pillars (not shown).

To electrically connect the wire bond component 54 to the first set of conductive features 48, a localized attachment process is used, wherein the various wire bonds 60 are attached to a conductive pad (not shown) on the wire bond component 54 and also to one of the first set of conductive features 48. First, heat, pressure, and/or ultrasonic energy may be applied directly to each one of the first set of conductive features 48 over which the wire bond 60 has been placed. Accordingly, each one of the wire bonds 60 is effectively welded to a corresponding one of the first set of conductive features 48.

To electrically connect the flip chip component 56 to the second set of conductive features 50, a solder reflow process is used, wherein the solder balls 62 of the flip chip component 56 are aligned with the second set of conductive features 50 and heat is applied in order to reflow the solder balls and form an electrical connection between the solder balls 62 and a corresponding one of the second set of conductive features 50. In the course of the reflow process, a portion of the protective finish 52 is dissolved surrounding each one of the solder balls 62. Notably, the thin layer of nickel is dissolved in order to allow each one of the solder balls 62, which may be tin, to directly contact a corresponding one of the second set of conductive features 50. Since the second set of conductive features 50 is generally copper, a copper-on-tin solder joint is formed in which the tin substantially dissolves into the copper, thereby resulting in improved reliability and electrical characteristics when compared to the use of conventional protective finishes.

FIG. 5C shows details of one of the conductive features (either from the first set of conductive features 48 or the second set of conductive features 50) according to one embodiment of the present disclosure. As shown in FIG. 5C, a conductive feature 48/50 is substantially surrounded by the protective finish 52, which includes a first layer 64, a second layer 66 over the first layer 64, and a third layer 68 over the second layer 66. As discussed above, the first layer 64 is a layer of nickel less than 1 μm thick. The second layer 66 may be palladium that is between about 0.03 μm and 0.2 μm thick. The third layer 68 may be a layer of gold that is between about 0.03 μm and 0.15 μm thick. As discussed above, such a protective finish is suitable for applications involving both wire bond and flip chip components, which may significantly streamline the manufacture of the electronics module 44 as discussed below.

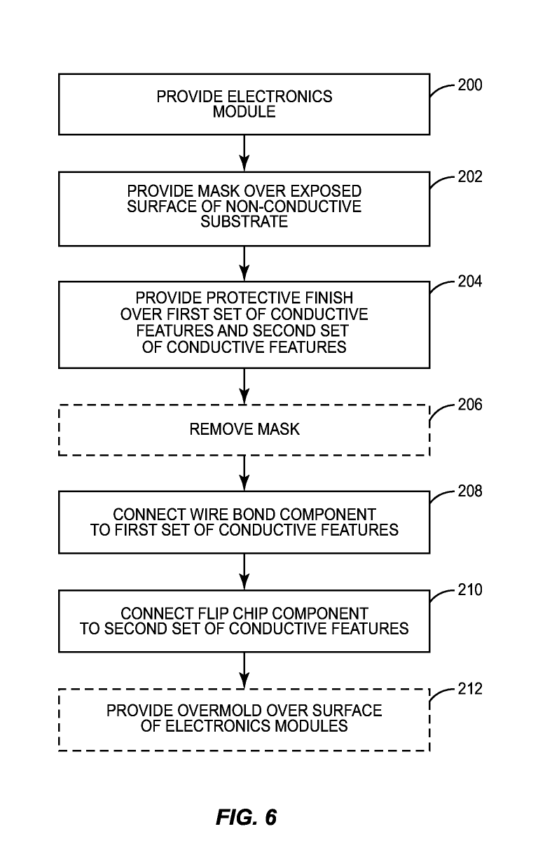

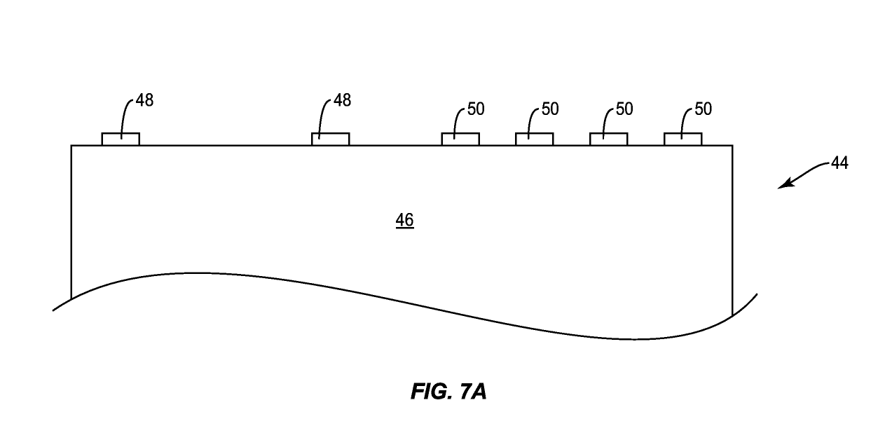

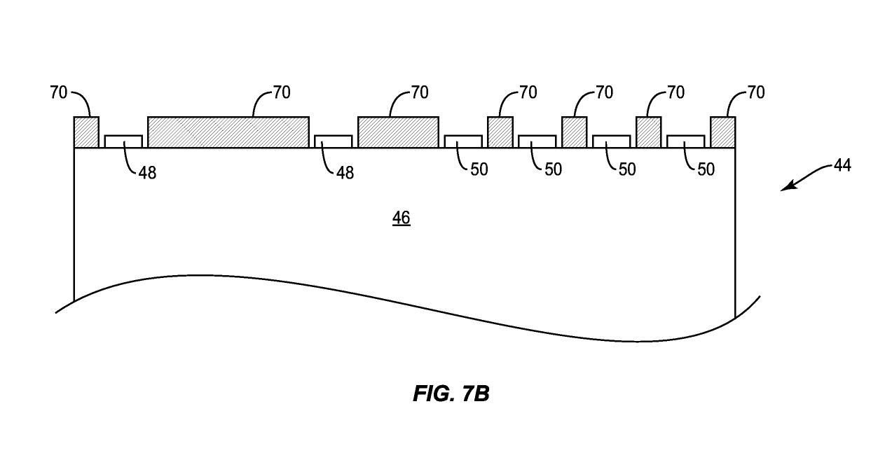

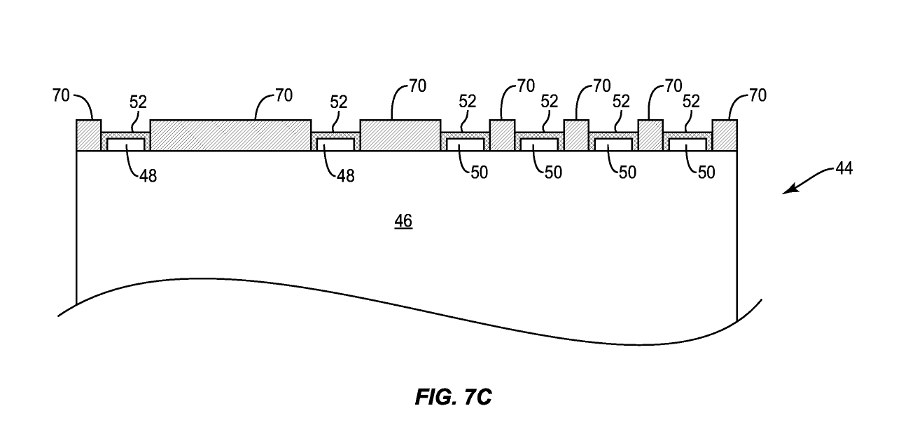

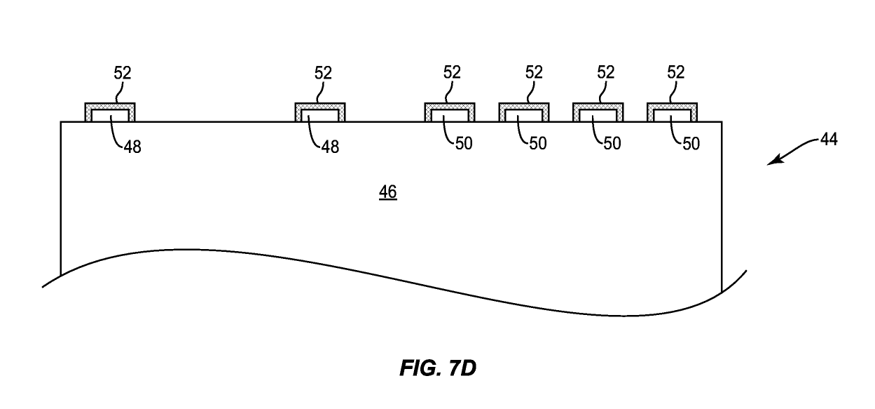

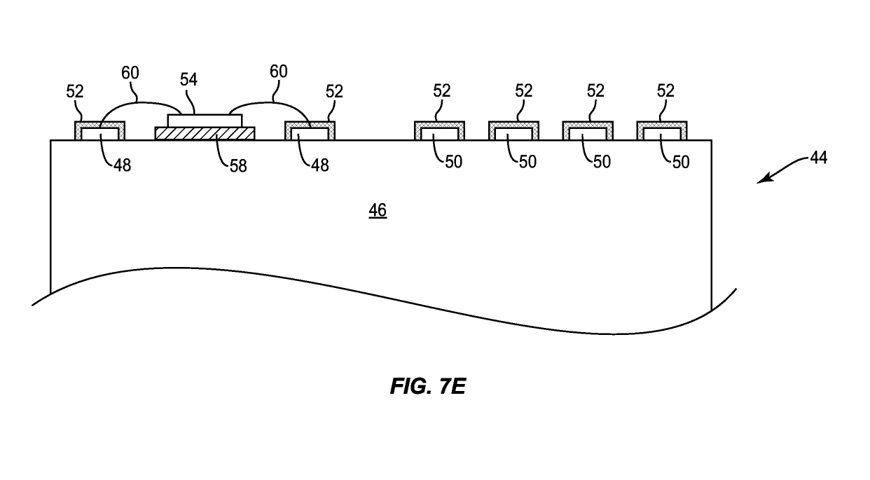

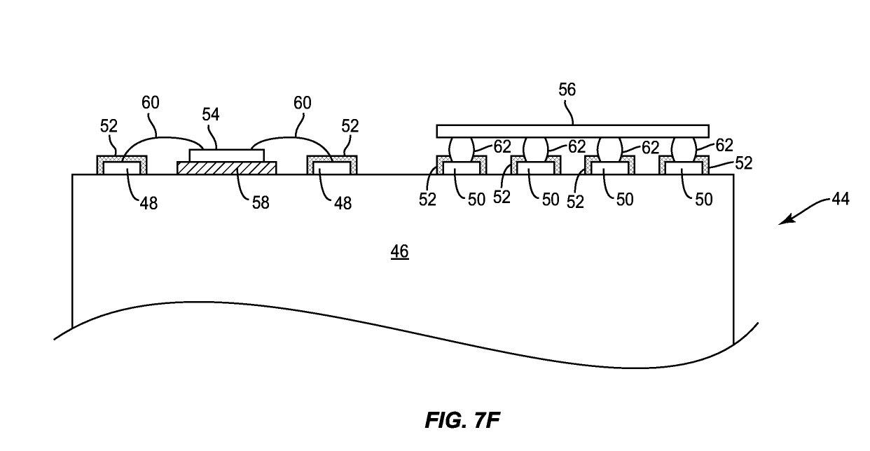

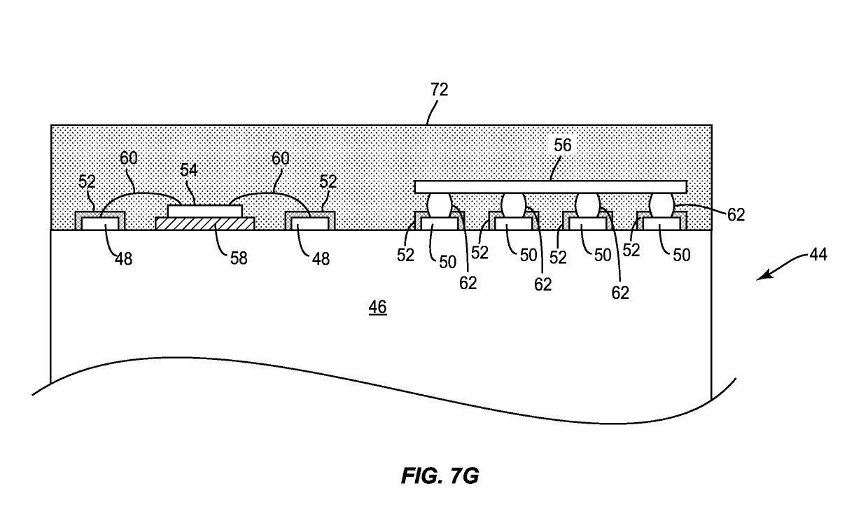

FIGS. 6 and 7A through 7G illustrate a method for manufacturing the electronics module 44 shown above according to one embodiment of the present disclosure. First, the electronics module 44 is provided (step 200 and FIG. 7A). As discussed above, the electronics module 44 includes the non-conductive body 46, the first set of conductive features 48, and the second set of conductive features 50. A mask 70 is then provided over the exposed portions of the surface of the non-conductive body 46 on which the first set of conductive features 48 and the second set of conductive features 50 are located (step 202 and FIG. 7B). Providing the mask 70 may include first applying the mask over the entirety of the surface of the non-conductive body 46, the first set of conductive features 48, and the second set of conductive features 50, then patterning the mask, for example, via a photolithography process to form the desired openings for the first set of conductive features 48 and the second set of conductive features 50.

The protective finish 52 is then provided over the first set of conductive features 48, and the second set of conductive features 50 (step 204 and FIG. 7C). Notably, the same protective finish 52 is provided over both the first set of conductive features 48 and the second set of conductive features 50. Accordingly, a single mask 70 may be used, which significantly streamlines the manufacturing process when compared to conventional solutions. The mask 70 may then optionally be removed (step 206 and FIG. 7D). Removing the mask may be accomplished by a mechanical or chemical etching process. The wire bond component 54 is then coupled to the first set of conductive features 48 (step 208 and FIG. 7E). As discussed above, coupling the wire bond component 54 to the first set of conductive features 48 may involve providing heat, pressure, and/or ultrasonic energy to each one of the first set of conductive features 48 while providing a wire bond 60 on a corresponding one of the first set of conductive features 48.

The flip chip component 56 is then coupled to the second set of conductive features 50 (step 210 and FIG. 7F). As discussed above, coupling the flip chip component 56 to the second set of conductive features 50 may involve aligning the solder balls 62 of the flip chip component 56 and performing a solder reflow process to reflow the solder balls 62 and couple the flip chip component 56 to the second set of conductive features 50. Finally, an optional step of providing an overmold 72 over the surface of the non-conductive body 46, the first set of conductive features 48, the second set of conductive features 50, the wire bond component 56, and the flip chip component 58 (step 212 and FIG. 7G). The overmold 72 may hold the wire bond component 54 and the flip chip component 56 in place and protect the various components from environmental exposure and/or external forces.

Those skilled in the art will recognize improvements and modifications to the preferred embodiments of the present disclosure. All such improvements and modifications are considered within the scope of the concepts disclosed herein and the claims that follow.

What is claimed is:

1. An electronics module comprising:
a non-conductive body;
a first set of conductive features on a surface of the non-conductive body, the first set of conductive features configured to connect to a wire bond component;
a second set of conductive features on the surface of the non-conductive body, the second set of conductive features configured to connect to a flip chip component; and
a protective finish over the first set of conductive features and the second set of conductive features, the protective finish comprising a layer of nickel less than 1 μm thick, a layer of palladium over the layer of nickel, and a layer of gold over the layer of palladium.

2. The electronics module of claim 1 wherein the first set of conductive features and the second set of conductive features are copper.

3. The electronics module of claim 1 wherein the layer of palladium is between about 0.03 μm and 0.2 μm thick.

4. The electronics module of claim 3 wherein the layer of gold is between about 0.03 μm and 0.15 μm thick.

5. The electronics module of claim 1 wherein the layer of gold is between about 0.03 μm and 0.15 μm thick.

6. The electronics module of claim 1 further comprising:
a wire bond component coupled to the first set of conductive features; and
a flip chip component coupled to the second set of conductive features.

7. The electronics module of claim 6 wherein the protective finish substantially dissolves in a bonding process connecting the flip chip component and the second set of conductive features such that a solder joint connecting each one of the second set of conductive features to the flip chip component substantially comprises tin.

8. The electronics module of claim 6 further comprising an overmold over the wire bond component, the flip chip component, and any exposed portions of the surface of the electronics module.

9. The electronics module of claim 1 wherein the non-conductive body is a laminate material.

10. The electronics module of claim 1 wherein the electronics module is a radio frequency (RF) electronics module.

11. A method of manufacturing an electronics module comprising:
providing a non-conductive body comprising:
a first set of conductive features on a surface of the non-conductive body, the first set of conductive features configured to connect to a wire bond component; and
a second set of conductive features on the surface of the non-conductive body, the second set of conductive features configured to connect to a flip chip component; and
providing a protective finish over the first set of conductive features and the second set of conductive features, the protective finish comprising a layer of nickel less than 1 μm thick, a layer of palladium over the layer of nickel, and a layer of gold over the layer of palladium.

12. The method of claim 11 wherein the first set of conductive features and the second set of conductive features are copper.

13. The method of claim 11 wherein the layer of palladium is between about 0.03 μm and 0.2 μm thick.

14. The method of claim 13 wherein the layer of gold is between about 0.03 μm and 0.15 μm thick.

15. The method of claim 11 wherein the layer of gold is between about 0.03 μm and 0.15 μm thick.

16. The method of claim 11 further comprising:
connecting a wire bond component coupled to the first set of conductive features; and
connecting a flip chip component coupled to the second set of conductive features.

17. The method of claim 16 wherein the protective finish substantially dissolves in a bonding process connecting the flip chip component and the second set of conductive features such that a solder joint connecting each one of the second set of conductive features to the flip chip component substantially comprises tin.

18. The method of claim 16 further comprising providing an overmold over the wire bond component, the flip chip component, and any exposed portions of the surface of the electronics module.

19. The method of claim 11 wherein the non-conductive body is a laminate material.

20. The method of claim 11 wherein the electronics module is a radio frequency (RF) electronics module.

21. The method of claim 11 wherein providing the protective finish over the first set of conductive features and the second set of conductive features comprises:
providing a mask over the exposed portions of the surface of the non-conductive body;
providing the protective finish over the first set of conductive features and the second set of conductive features; and
removing the mask.
